(19) United States
(12) Patent Application Publication
(10) Pub. No.: US 2012/0019401 A1
(43) Pub. Date: Jan. 26, 2012

(54) DATA ENTRY DEVICE WITH FLEXIBLE SHEET

(75) Inventors: KUN-TSAN WU, Shindian (TW); LI-WEN TIEN, Shindian (TW)

(73) Assignee: FIH (HONG KONG) LIMITED, Kowloon (HK)

(21) Appl. No.: 12/944,855

(22) Filed: Nov. 12, 2010

(30) Foreign Application Priority Data
Jul. 21, 2010 (CN) 201010232913.8

(51) Int. Cl. H03M 11/00

(52) U.S. Cl. 341/22

(57) ABSTRACT

A data entry device includes a frame having a pad, a flexible base, a sleeve, a handle, a rolling mechanism, and a stop mechanism. The base is received in the sleeve. The flexible base is attached to the frame for interacting with the pad for inputting information. The handle is detachably attached to the sleeve. The rolling mechanism is for rotating the base, one end of the base is secured to the rolling mechanism, and the other end of the base is secured to the handle. The stop mechanism controls the rotation of the rolling mechanism for preventing the flexible base rotating.

This application is one of the two related co-pending U.S. patent applications listed below. All listed applications have the same assignee and were concurrently filed herewith. The disclosure of each of the listed applications is incorporated by reference into all the other listed application.

| Attorney Docket No. | Title | Inventors |
|---|---|---|
| US33522 | FLEXIBLE DATA ENTRY DEVICE | Wu et al. |
| US33523 | DATA ENTRY DEVICE WITH | Wu et al. |
| | FLEXIBLE SHEET | |

### BACKGROUND

1. Technical Field

The disclosure generally relates to data entry devices and, particularly, to a flexible data entry device.

2. Description of Related Art

Conventional data entry devices for computers are made of a number of rigid/hard keys for inputting information. The keys are arranged in a standard QWERTY format. This kind of data entry device occupies a large space. Because of the size, it is inconvenient to relocate this kind of data entry device.

Therefore, there is room for improvement within the art.

### BRIEF DESCRIPTION OF THE DRAWINGS

Many aspects of the exemplary of a data entry device can be better understood with reference to the following drawings. The components in the drawings are not necessarily drawn to scale, the emphasis instead being placed upon clearly illustrating the principles of the data entry device for electronic device. Moreover, in the drawings, like reference numerals designate corresponding parts throughout the several views, in which:

FIG. 1 is an isometric view of a data entry device with a receiving assembly.

FIG. 2 is an exploded, isometric view of the receiving assembly with a base.

FIG. 3 is an enlarged view of a stop mechanism and a first cap of FIG. 2.

FIG. 4 is similar to FIG. 2, but viewed from another aspect.

FIG. 5 is similar to FIG. 3, but viewed from another aspect.

FIG. 6 is a cross sectional view of FIG. 1 taken along line VI-VI.

FIG. 7 is similar to FIG. 6, but showing another state.

FIG. 8 is an assembled view of the data entry device of FIG. 1, but in a closed state.

### DETAILED DESCRIPTION

The disclosure is illustrated by way of example and not by way of limitation in the accompanying drawings. It should be noted that references to “an” or “one” embodiment in this disclosure are not necessarily to the same embodiment, and such references can include the meaning of “at least one” embodiment where the context permits.

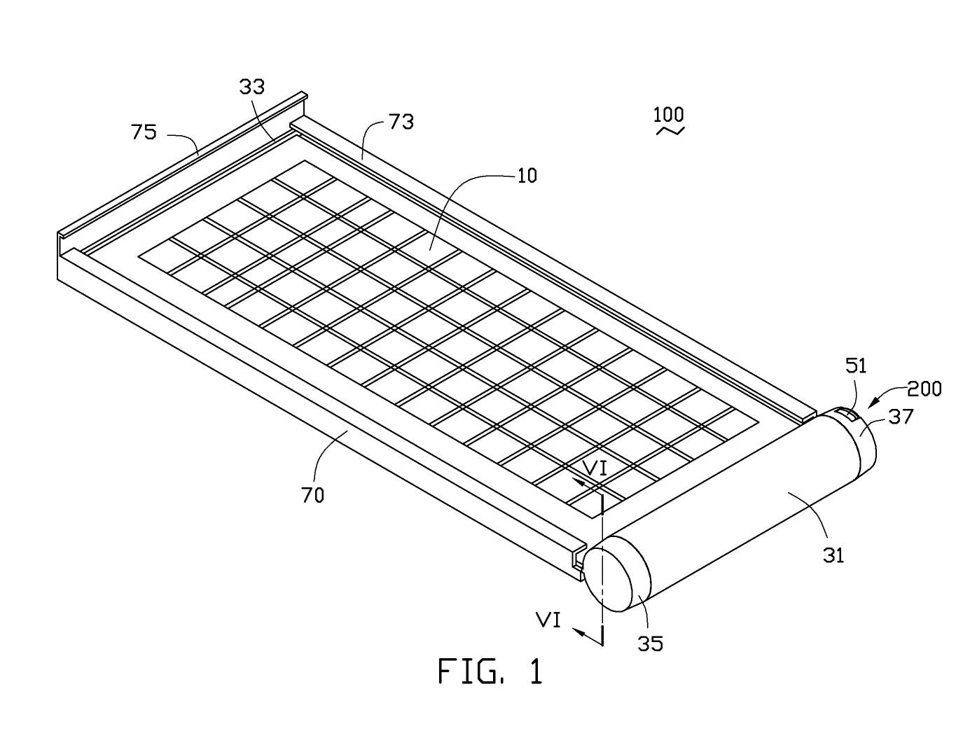

FIG. 1 illustrates a data entry device 100 for an electronic device (not shown), such as a personal computer (PC), or a notebook computer (NB). The data entry device 100 includes a flexible base 10, a frame 70, and a receiving assembly 200 detachably secured to one end of the frame 70. In this exemplary embodiment, the base 10 is a flexible touch panel with icons thereon used for inputting information to the electronic device. The base 10 is placed on the frame 70 during use and can be flexibly rolled up and received in the receiving assembly 200 when not in use.

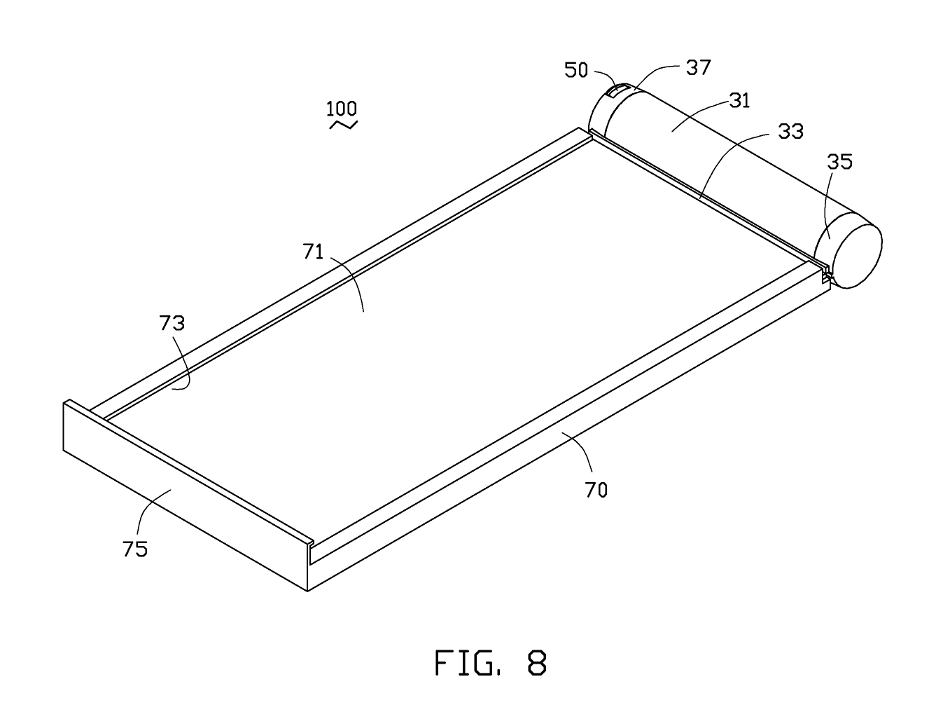

The frame 70 includes a pad 71 (see FIG. 8), two rails 73, and a positioning plate 75. The pad 71 is used to support the base 10 during use. The two rails 73 are oriented at opposite sides of the pad 71 to guide the handle 33 to slidethereunder. The positioning plate 75 is made of magnetic materials and is substantially perpendicularly attached to one end of the pad 71.

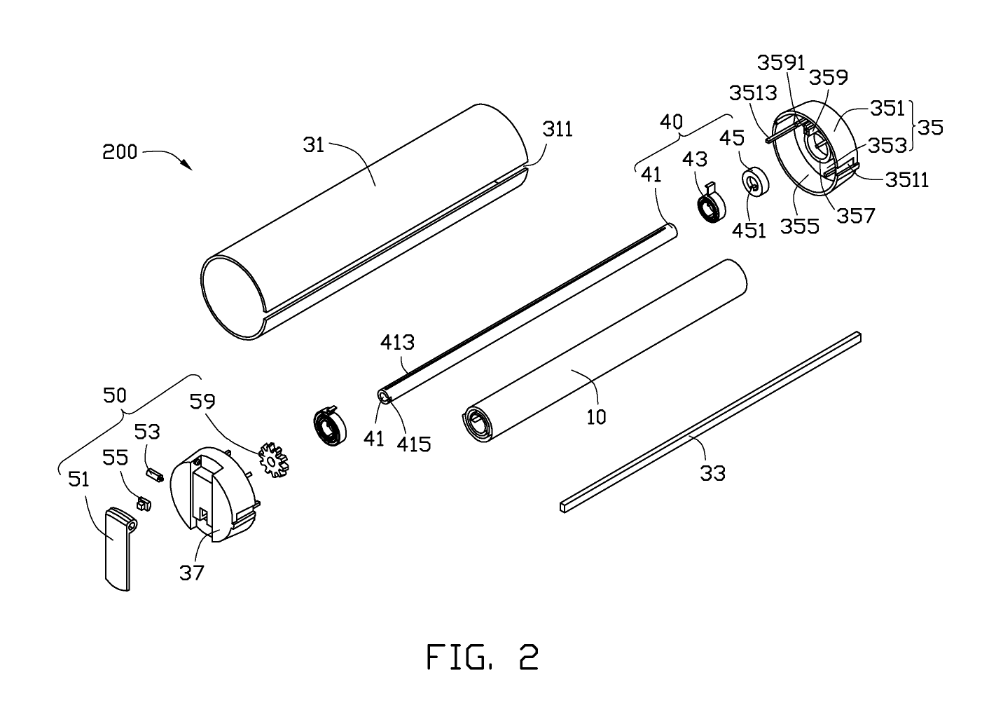

Referring to FIG. 2, the receiving assembly 200 includes a sleeve 31, a handle 33, a first cap 37, and a second cap 35, a rolling mechanism 40, and a stop mechanism 50. The base 10 is flexibly received in the sleeve 31. The rolling mechanism 40 is secured to one end of the sleeve 31 to roll or unroll the base 10. The stop mechanism 50 is secured to the other end of the sleeve 31 to stop the rolling mechanism 50. One end of the base 10 is fixed to the handle 33 and the other end of the base 10 is secured to the rolling mechanism 40. The handle 33 is made of magnetic materials and is magnetically secured to the sleeve 31. When the handle 33 is removed from the sleeve 31, the base 10 is rolled and unfolded. The first cap 37 is oriented at one end of the sleeve 31, and the second cap 35 is oriented at the other end of the sleeve 31. The stop mechanism 50 is mounted on the first cap 37 to stop the rolling mechanism 40. The rolling mechanism 40 is rotatably secured to the first and second caps 37 and 35. In the exemplary embodiment, the first and second covers 37 and 35 are made of magnetically attractive materials, thus, the handle 33 can be attracted by and be secured to the first and second covers 37 and 35 by magnetic force.

An entrance 311 is defined in the sleeve 31 to form a pass-through for the base 10. The handle 33 is substantially a rod and made of magnetic materials and used to draw the base 10 out of the sleeve 31 through the entrance 311. The handle 33 can slide under the rails 73 of the frame 70 and then magnetically attracted by the positioning plate 75.

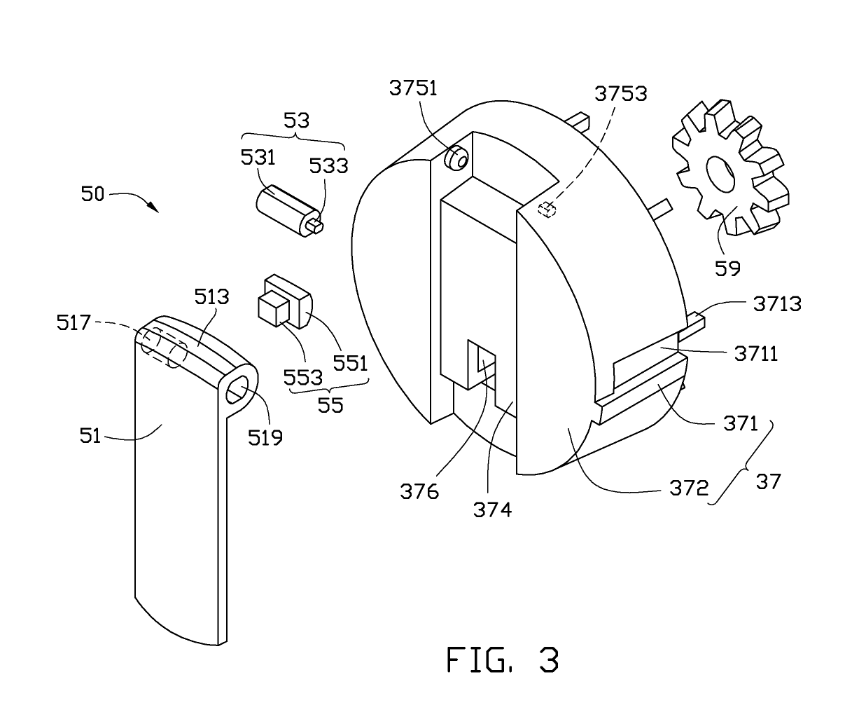

Referring to FIGS. 3 through 5, the first cap 37 includes a peripheral wall 371 and a bottom wall 372. A notch 3711 is defined in the outer surface of the peripheral 371, in which the handle 33 is received. A receiving space 373 is cooperatively defined by the peripheral wall 371 and the bottom wall 372. A number of supporting beams 3713 project from the inner surface of the peripheral wall 371 to support the sleeve 31. A first receiving groove 374 and a second receiving groove 375 are defined in the outer surface of the bottom wall 372, and the first receiving groove 374 communicates with the second receiving groove 375 and the second receiving groove 375 is deeper than the first receiving groove 374. A through hole 376 is defined in the bottom wall 372. The through hole 376 communicates with the first receiving groove 374 and the receiving space 373. A projection 3751 protrudes from the bottom wall 372 and extends into the first receiving groove 374. A receiving hole 3753 is defined in the bottom wall 373. The receiving hole 3753 aligns with the projection 3751. A post 377 and a block 378 project from the inner surface of the bottom wall 372 and each is substantially parallel to the peripheral wall 371. A receiving slot 3781 is defined in the block 378.

The second cap 35 includes a peripheral wall 351 and a bottom wall 353. A notch 3511 is defined in the outer surface of the peripheral 351, in which the handle 33 is received A receiving space 355 is cooperates with the peripheral wall 351 and the bottom wall 353. A number of supporting beams 3513 project from the inner surface of the peripheral wall 351 to support the sleeve 31. A ring portion 357 and a block 359 are spaced apart and project from the inner surface of the bottom wall 353. A slot 3591 is defined in the block 359.

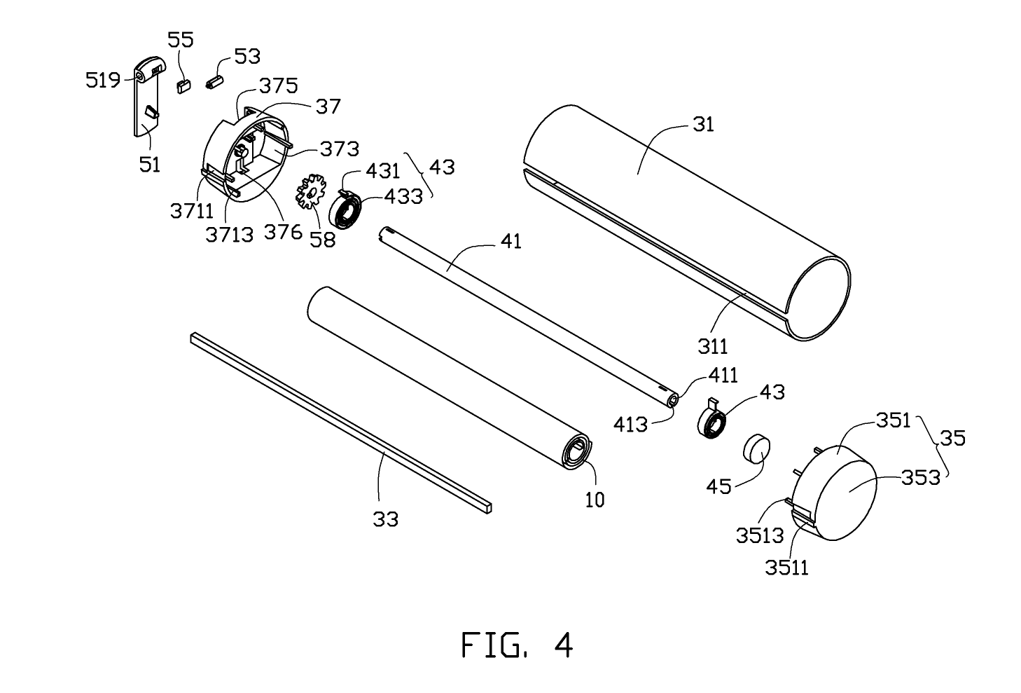

Referring FIG. 4, the rolling mechanism 40 includes a shaft 41, two scroll springs 43, and a bushing 45. The other end of the base 10 is fixed to the shaft 41. The scroll springs 43 are for rotating the shaft 41. The bushing 45 is rotatably secured to the second cap 35 and supports the shaft 41.

The shaft 41 is a cylindrical sleeve with a bore 411 therethrough. An opening 413 and a cutout 415 are defined therein. The opening 413 is substantially parallel to the bore 411 and is for receiving the other end of the base 10. The cutout 415 is defined in one end of the shaft 41 and communicates with the bore 411. Each scroll spring 43 includes a first stopper portion 431 at one end and a second stopper portion 433 at the other end. A protrusion 451 projects from the bushing 45, the protrusion 451 is received in the opening 413.

The stop mechanism 50 includes an operating element 51, a hinge 53, an elastic element 55, and a stop wheel 59. The operating element 51 is pivotably secured to the first cap 37 by the hinge 53 and the projection 3751. The elastic element 55 is secured to the operating element 51 and elastically resists the operating element 51 when the operating element 51 rotates relative to the first cap 37. The shaft 41 is fixed together with the stop wheel 59, thus, when the stop wheel 59 is stopped by the operation element 51, the shaft 41 stops rotating.

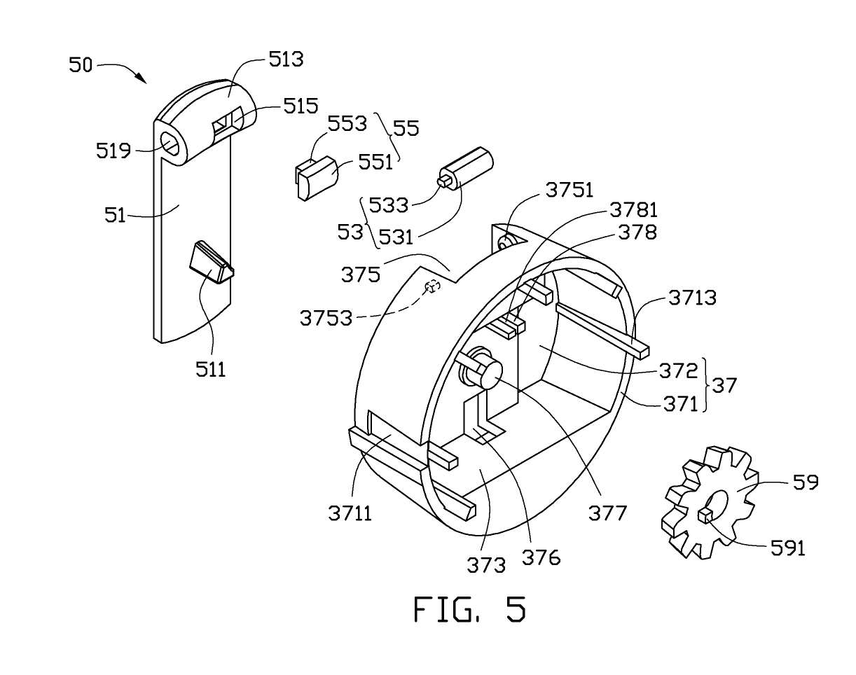

Referring FIGS. 3 and 5, an arm 511 and a connecting portion 513 spaced apart, project from the operating element 51. A stepped receiving cavity 515 is defined in the connecting portion 513, in which the elastic element 55 is received. A first receiving hole 517 is defined in one side of the operating element 51, in which the hinge 53 is received. And a second receiving hole 519 is defined in the other side of the operating element 51, in which the projection 3751 of the first cap 37 is received. The hinge 53 includes a housing 531 and a pivot 533 pivotably connected to the housing 531.

The elastic element 55 includes a resisting portion 551 and a fixing portion 553. The resisting portion 551 is integrality formed with the fixing portion 553. A latching portion 591 projects from the stop wheel 59, the latching portion 591 is received in the cutout 415 of the shaft 41. In the exemplary embodiment, the stop wheel 59 is a ratchet wheel. When the stop arm 511 resists the stop wheel 59, the stop wheel 59 can rotate in a single direction, for example, in a clockwise direction.

During assembly, first, the receiving assembly 200 is assembled. One end of the base 10 is received in the bore 411 and is fixed to the shaft 41. The shaft 41 is inserted into the sleeve 31, the other end of the base 10 passes through the entrance 311 of the sleeve 31. The second stopper portion 433 of each scroll spring 43 is fixed to the shaft 41, and each scroll spring 43 is coiled around the shaft 41. The stop wheel 41 is fixed to one end of the shaft 41, and the latching portion 591 is received in the cutout 415. The bushing 45 is fixed to the other end of the shaft 41 and is then rotatably received in the ring portion 357 of the second cap 35. Then, the post 377 passes through the stop wheel 59 and is received in the bore 411 of the shaft 41. Thus, one end of the first shaft 41 is rotatably secured to the first cap 37, and the other end is rotatably secured to the second cap 35.

Then, the second stopper portion 433 of one of the scroll springs 43 is inserted into the slot 3591 of the second cap 35 and is retained by the block 359. Similarly, the other scroll spring 43 is fixed to the first cap 37. The connecting beams 3513 and 3713 resist the inner surface of the sleeve 31, and the sleeve 31 is secured together with the first cap 37 and the second cap 35.

The stop mechanism 50 is secured to the first cap 37 to control the movement of the shaft 41. The fixing portion 553 of the elastic element 55 is received in the stepped receiving cavity 515 and is fixed to the operating element 51. When the elastic element 55 is fixed to the operating element 51, the resisting portion 551 projects from the connecting portion 513. The hinge 53 is inserted into the first receiving hole 517 with the pivot 533 extending from the side wall of the connecting portion 513. The pivot 533 is rotatably received in the receiving hole 3753, and the projection 3751 is rotatably received in the second receiving hole 519. The other end of the base 10 is fixed to the handle 33. Finally, the receiving assembly 200 is attached to the frame 70 opposite to the positioning plate 75 with a fastener (not show), with the handle 33 aligning the rails 75.

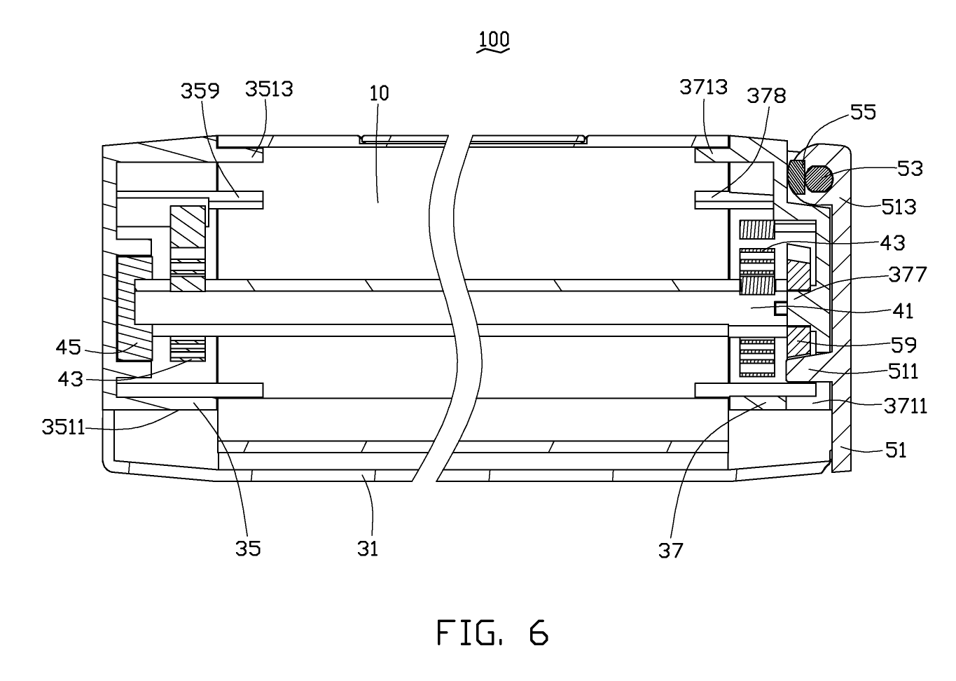

Referring to FIGS. 5 and 6, when the data entry device 100 is in a folded state, the arm 511 is received in the stop wheel 59 and stops the stop wheel 59 from rotating in counterclockwise direction. The handle 31 is detachably attached to the sleeve 31 and is attracted by the first cap 37 and the second cap 35 by magnetic force. One end of the operating element 51 is received in the notch 331 of the handle 31. The frame 70 can be separated from the receiving assembly 200, thus, the data entry device 100 can be easy to carry.

When the data entry device 100 is to be used to input information, first, the frame 70 is secured to the receiving assembly 200, the handle 33 is removed from the sleeve 31 by external force. The handle 33 is pulled to slide under the rails 73 and is then fixed to the positioning plate 75 by magnetic force between the positioning plate 75 and the handle 33. When the handle 33 moves, the base 10 is pulled out of the sleeve 31 by the entrance 311 and drives the shaft 41 to rotate. At the same time, the scroll springs 43 are elastically deformed by the shaft 41. Thus, the base 10 is pulled out of the sleeve 31 and can be used to input information when the data entry device 100 is electrically connected to the portable electronic device, as shown in FIG. 1.

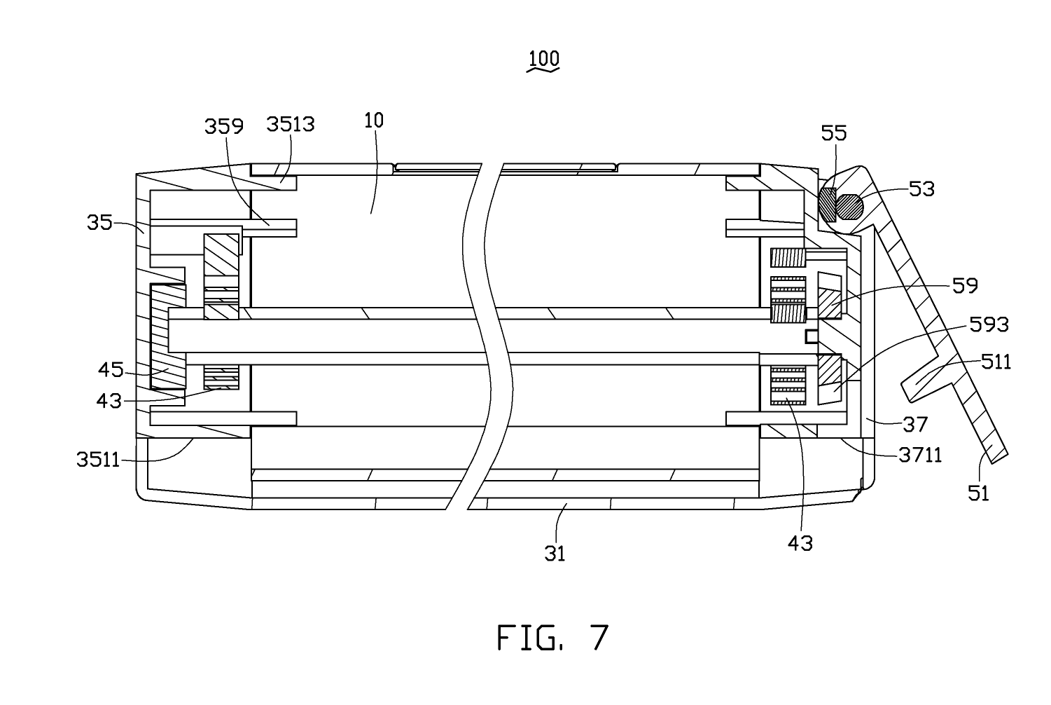

Referring to FIG. 7, when the user finishes inputting, the base 10 is rolled back up, the user separates the handle 33 from the position, the operating element 51 is drawn out of the groove 374 and is rotated relative to the first cap 37. The arm 511 is removed from the stop wheel 59, the stop wheel 59 is driven to rotate counterclockwise under the elastic force of the scroll springs 43, then, the base 10 is pulled and coiled around the shaft 41 and is received in the sleeve 31, the handle 33 is received in the notches 3511 and 3711.

In the exemplary embodiments of the data entry device 100, the flexible base 10 attached to the frame 70 for interacting with the pad 71 for inputting information, and the base 10 can be removed from the frame 70 and be received in the receiving assembly 200, and the receiving assembly 200 can be separated from the frame 70. The rolling mechanism 40 is used to roll the base 10 to allow the base 10 to automatically receive in the sleeve 31, such that the data entry device 100 is easy to carry and clean.

It is to be understood that the base 10 can be just a flexible sheet with icons thereon, and the pad 71 comprises a touch panel, when the base 10 covers the pad 71, the icons on the base identify the positions of buttons to be pressed.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A data entry device comprising:
a frame having a pad;
a flexible base attached to the frame for interacting with the pad for inputting information; and
a receiving assembly including:
a sleeve;
a handle detachably attached to the sleeve, one end of the base secured to the handle;
a rolling mechanism, the other end of the base secured to the rolling mechanism, the rolling mechanism rotating the base to allow the base to be received in the sleeve; and
a stop mechanism controlling the movement of the rolling mechanism for prevent the flexible base rotating.

2. The data entry device as claimed of claim 1, wherein an entrance is defined in the sleeve, through which the base passes.

3. The data entry device as claimed of claim 1, wherein the receiving assembly further includes a first cap and a second cap, the first and second caps are secured to opposite end of the sleeve, and the stop mechanism is secured to the first cap.

4. The data entry device as claimed of claim 3, wherein the rolling mechanism includes a shaft and a scroll spring, the shaft is rotatably attached to the first and second covers, one end of the scroll spring is fixed to either the first cover or the second cover, and the other end of the scroll spring is fixed to the shaft.

5. The data entry device as claimed of claim 3, wherein the stop mechanism includes an operating element and a stop wheel, the operating element includes an arm, the operating element is pivotably attached to the first cover, the stop wheel is fixed to the shaft, the arm can prevent the stop wheel from rotating.

6. The data entry device as claimed of claim 5, wherein the stop wheel is a ratchet wheel.

7. The data entry device as claimed of claim 6, wherein the stop mechanism further includes a hinge and an elastic element, the operating element is pivotably secured to the first cover by the hinge, the elastic element is received in the operating element and elastically resists the operating element when the operating element rotates.

8. The data entry device as claimed of claim 3, wherein a plurality of connecting beams extend from inner surfaces of the first and second caps, the beams support the sleeve.

9. The data entry device as claimed of claim 1, wherein the base is a touch panel.

10. The data entry device as claimed of claim 1, wherein the base has icons thereon and the pad is a touch panel having touch locations corresponding to the base icons.

11. The data entry device as claimed of claim 1, wherein the frame includes two rails and a positioning plate, the handle can slide under the rails and magnetically attract to the positioning plate.

12. A data entry device comprising:
a frame imbedding a touch pad thereof;
a flexible sheet with icons thereon, the icons identifying input positions to be pressed when the flexible sheet covers the touch pad;
a sleeve, in which the sheet is received;
a handle detachably attached to the sleeve;
a rolling mechanism, one end of the sheet secured to the rolling mechanism, and the other end of the sheet secured to the handle; and
a stop mechanism controlling the rotation of the rolling mechanism for preventing the flexible sheet rotating.

13. The data entry device as claimed of claim 12, wherein an entrance is defined in the sleeve, in which the sheet passes through.

14. The data entry device as claimed of claim 12, wherein further including a first cap and a second cap, the first and second caps being secured to opposite ends of the sleeve, and the stop mechanism being secured to the first cap.

15. The data entry device as claimed of claim 14, wherein the rolling mechanism includes a shaft and a scroll spring, the shaft is rotatably attached to the first and second covers, one end of the scroll spring is fixed to either the first cover or the second cover, and the other end of the scroll spring is fixed to the shaft.

16. The data entry device as claimed of claim 14, wherein the stop mechanism includes an operating element and a stop wheel, the operating element includes an arm, the operating element is pivotably attached to the first cover, the stop wheel is fixed to the shaft, the arm can prevent the stop wheel from rotating.

17. The data entry device as claimed of claim 16, wherein the stop wheel is a ratchet wheel.

18. The data entry device as claimed of claim 17, wherein the stop mechanism further includes a hinge and an elastic element, the operating element is pivotably secured to the first cover by the hinge, the elastic element is received in the operating element and elastically resists the operating element when the operating element rotates.

19. The data entry device as claimed of claim 14, wherein a plurality of connecting beams extend from inner surfaces of the first and second caps, the beams support the sleeve.

20. The data entry device as claimed of claim 13, wherein the frame includes two rails and a positioning plate, the handle can slide under the rails and magnetically attract to the positioning plate.
